(19) United States
(12) Patent Application Publication
(10) Pub. No.: US 2017/0081183 A1
(43) Pub. Date: Mar. 23, 2017

(54) MICROMECHANICAL LAYER SYSTEM

(71) Applicant: Robert Bosch GmbH, Stuttgart (DE)

(72) Inventors: Simon Armbruster, Wannweil (DE); Rainer Straub, Ammerbuch (DE); Stefan Pinter, Reutlingen (DE); Ralf Hausner, Reutlingen (DE); Dietmar Haberer, Reutlingen (DE); Johannes Baader, Freiburg (DE)

(21) Appl. No.: 15/311,354

(22) PCT Filed: May 29, 2015
(86) PCT No.: PCT/EP2015/061941

§ 371 Date: Nov. 15, 2016

(30) Foreign Application Priority Data
Jun. 10, 2014 (DE) 102014210986.8

(51) Int. Cl. B81C 1/00; G02B 26/08; B81B 7/00

(52) U.S. Cl. CPC B81C 1/00801; B81B 7/0025; G02B 26/0833; B81B 2201/042; B81B 2203/0163; B81C 2203/0145; B81C 2201/014

(57) ABSTRACT

A micromechanical layer system, having at least two mechanically active functional layers patterned independently of each other, which are arranged vertically one on top of the other and are functionally coupled to each other.

### FIELD

The present invention relates to a micromechanical layer system and to a method for producing a micromechanical layer system.

### BACKGROUND INFORMATION

In MEMS components (e.g., inertial sensors), frequently two, sometimes even three wafers are used for producing the component. For producing more complex components, such as for example micromirrors or similarly complex structures, a layer system having relatively few layers is highly limiting or respectively requires a greater chip area in the horizontal extension. Some MEMS components (microelectromechanical systems) dispense with hermetic capping in favor of a simpler layer stack and thereby accept disadvantages in further processing, such as for example separation and packaging, and must use a very elaborate housing in order to fulfill for example requirements of the ambient pressure for operating the MEMS.

### SUMMARY

It is an object of the present invention to provide an improved layer system for a micromechanical component.

According to a first aspect, the object of the present invention is achieved by a micromechanical layer system, which includes:
at least two mechanically active functional layers, patterned independently of each other, which are arranged vertically one on top of the other and are functionally coupled to each other.

In this manner, mechanically coupled structures are provided in two different wafers, which may be patterned independently of each other.

In particular, it is possible to process the two wafers independently of each other before joining them.

In this manner, the structures of the first functional layer advantageously do not depend on the structures of the second functional layer. This supports a high vertical integration density, which in effect supports a small area extension of a completed micromechanical component.

Preferred specific embodiments of the micromechanical layer system are the subject matter of subclaims.

One advantageous development of the micromechanical layer system is characterized by the fact that at least one of the two functional layers has a spring element. This supports an effective mechanical coupling of the two functional layers and a high degree of mobility of the two functional layers.

Another advantageous development of the layer system is characterized by the fact that a bottom side of the second functional layer has a reflective coating. This makes the layer system very well suited for micromirror applications that require a highly reflective layer.

Another advantageous development of the layer system is characterized by the fact that the second functional layer is an SOI wafer or an Si wafer. This advantageously increases a free space for design for the second functional layer. In particular, using an SOI wafer makes it possible to dimension a depth of holes in the second functional layer very precisely.

Another advantageous development of the layer system is characterized by the fact that the layer system is capped on top by a third functional layer and on the bottom by a fourth functional layer. This advantageously makes it possible that the micromechanical structure is able to move freely upward and that for example a magnet may be cemented onto the third functional layer. The hermetic closure of the entire layer system advantageously facilitates a further processing of the layer system, e.g., for the purpose of separating chips in that, e.g., no sawing fluid is able to enter.

Another advantageous development of the layer system is characterized by the fact that the third functional layer has notches on top. This makes it possible to form markings, which may be used for identifying sawing paths or for an exact positioning of magnets.

Another advantageous development of the layer system is characterized by the fact that the fourth functional layer is designed to be planar or kinked. This makes it possible to design a reflective behavior of the reflective layer in a suitable manner.

Another advantageous specific embodiment of the layer system is characterized by the fact that a defined gas atmosphere is enclosed in a cavity between the functional layers. This is preferably achieved in that a defined gas atmosphere is enclosed in the layer system during the final bonding step. It is possible to enclose a protective gas in the form of nitrogen, neon, etc. or a vacuum for the best possible damping behavior of the micromechanically movable structures.

The present invention is described below in detail with additional features and advantages on the basis of several figures. All features form the subject matter of the present invention, irrespective of their representation herein or in the figures. The figures are not necessarily true to scale and are in particular meant to illustrate the principles of the present invention.

### BRIEF DESCRIPTION OF THE PRESENT INVENTION

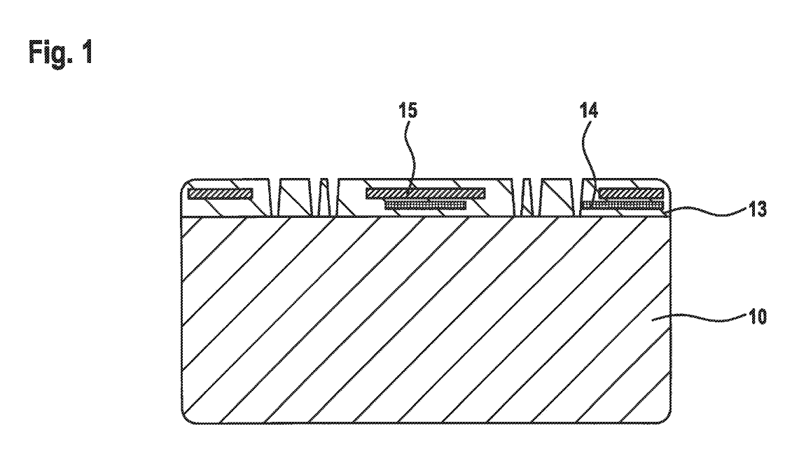

FIG. 1 shows a cross section through a first functional layer of the micromechanical layer system.

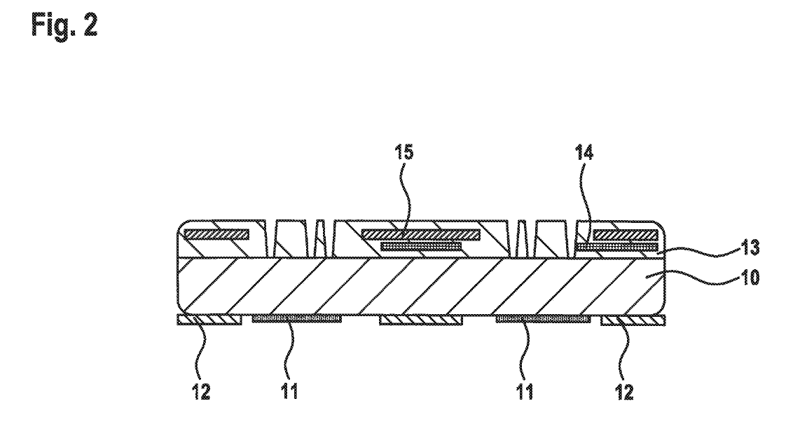

FIG. 2 shows a cross section through the first functional layer following a thinning process.

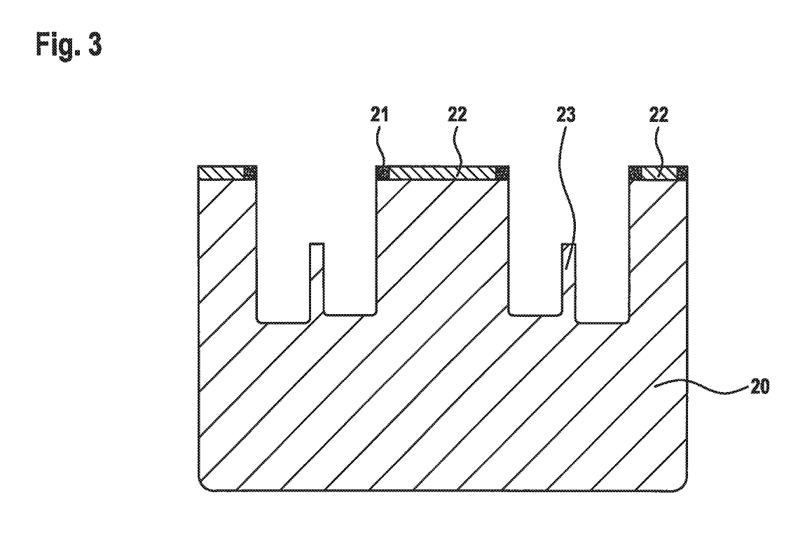

FIG. 3 shows a cross section through a second functional layer of the micromechanical layer system.

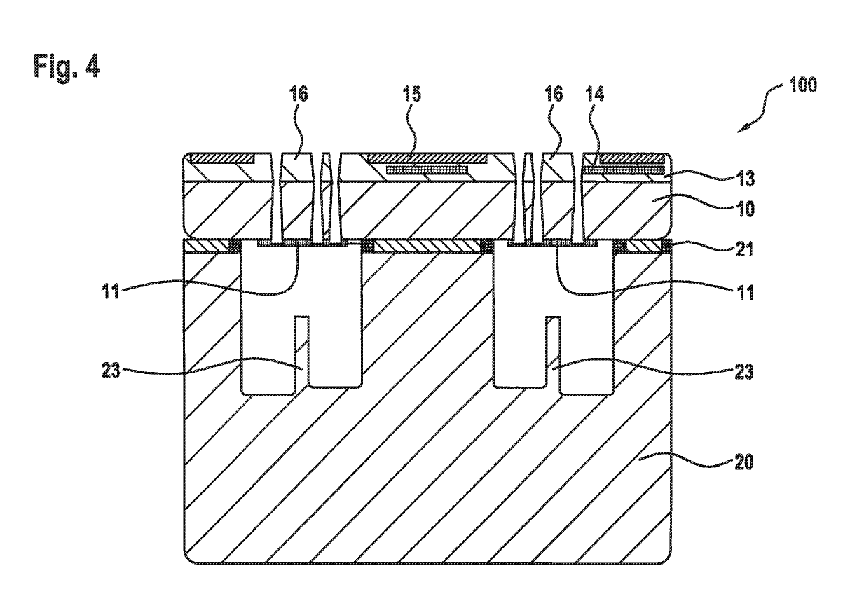

FIG. 4 shows a cross section through a layer system of a first and a second functional layer.

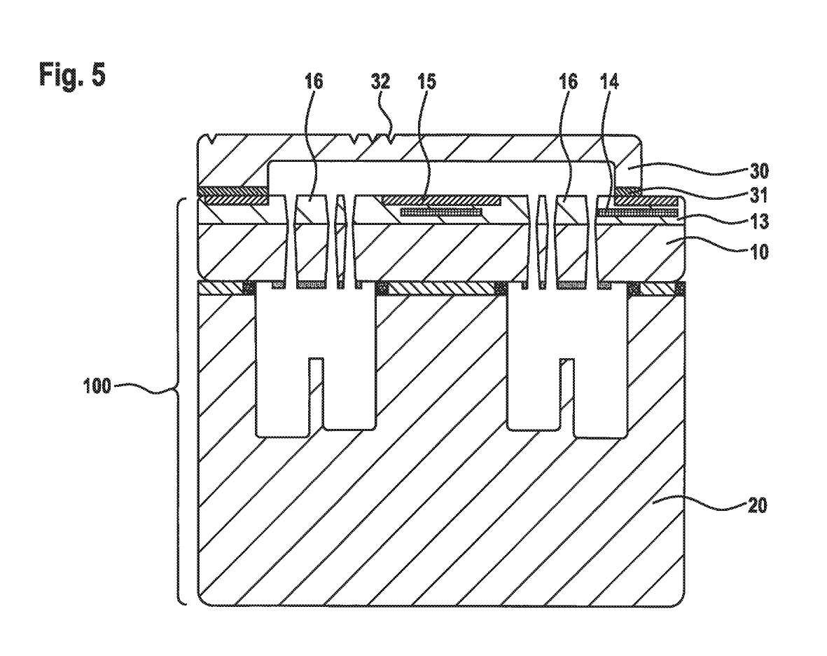

FIG. 5 shows a cross section through a capped micromechanical layer system.

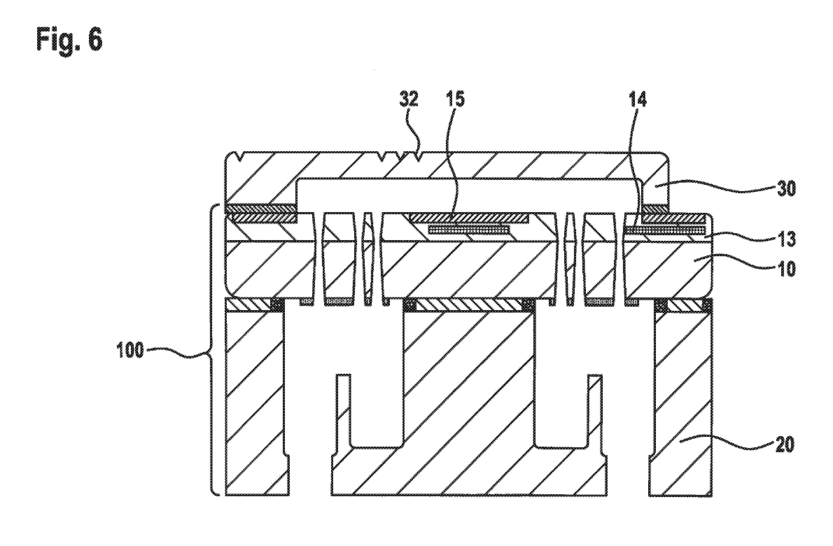

FIG. 6 shows a cross section through a processed capped micromechanical layer system.

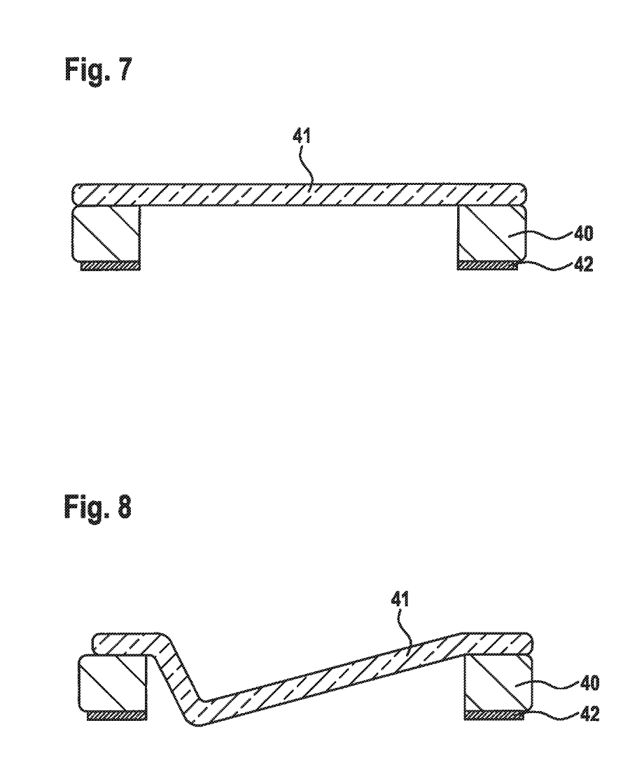

FIG. 7 and FIG. 8 show two variants of transparent functional layers for covering the layer system from below.

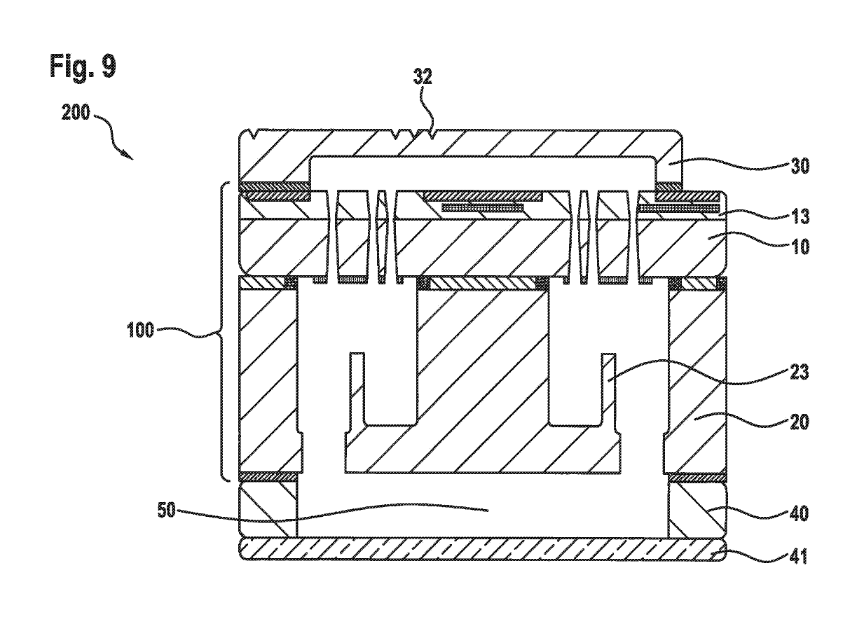

FIG. 9 shows a cross section of a complete layer system having all four functional layers.

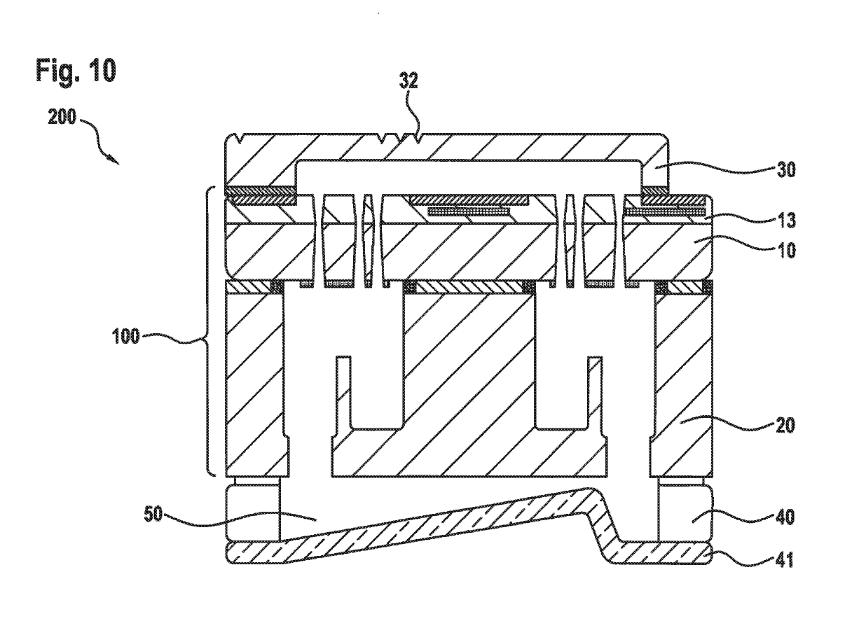

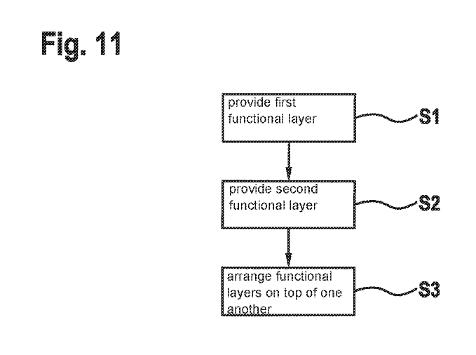

FIG. 10 shows a cross section of an alternative layer system having all four functional layers.

FIG. 11 shows a basic sequence of one specific embodiment of the method according to the present invention.

### DETAILED DESCRIPTION OF EXAMPLE EMBODIMENTS

FIG. 1 shows a first functional layer 10 or a first substrate or a first wafer in a cross-sectional view. On the front side of first functional layer 10, it is possible to produce any electrically active structures such as, e.g., piezoresistors (not shown) or copper coils 14 or an electrical contacting layer 15 (e.g., metalization) for conducting suitable electric currents. A passivation layer 13 is applied as the uppermost layer, which protects the mentioned structures when processing first functional layer 10 further. From this functional layer 10, it is later possible to etch MEMS structures such as spring elements 16 for example.

It may be seen from FIG. 2 that the first functional layer 10 is ground back to the target thickness desired later and is provided on the back side for example with etch stop layers 11 and bond materials 12 for wafer bonding to the next functional layer.

As indicated in FIG. 3, in the next step, a second functional layer 20 or a second wafer is patterned on the front side and is possibly (depending on the utilized bonding method) provided with a bond material 22 for wafer bonding to first functional layer 10. Oxide 21 may be seen laterally with respect to bond material 22. Second functional layer 20 may be developed as an SOI wafer (silicon-on-insulator, not shown), in which a prepatterning stops on the buried oxide layer. This makes it possible to set a depth of etchings very precisely because it is possible to stop the etching process from the top side. A use of a double SOI wafer (not shown) having two buried oxide layers is also possible. In this case, it is possible to produce a mirror diaphragm not only (as described further below) by thinning, but also by etching with a stop on the second buried oxide layer. This may be advantageous in particular when producing very thin diaphragms having narrow thickness tolerances.

The patterning of second functional layer 20 may be performed using known silicon etching methods such as for example trench etching or etching in potassium hydroxide (KOH). The patterning may fulfill any desired functions in the finished MEMS component such as for example a reinforcement of the optically utilized diaphragm surface in a micromirror by way of reinforcing elements 23. Reinforcing elements 23 serve in particular as a mechanical strengthening or reinforcement of the optically active surface.

FIG. 4 shows in a cross section that first and second functional layers 10, 20 are joined by a suitable bonding method. This may be one of the known methods such as for example silicon-silicon direct bonding or eutectic bonding using for example aluminum and germanium or gold or thermocompression bonding using gold, anodic bonding or a comparable method.

The bond is dynamically stressed in the operation of the MEMS element, and a suitable bonding method should therefore be selected. In the bonded state, it is now possible to perform the further patterning of first functional layer 10. Here it is possible for example to produce, by way of trench etching or other suitable silicon patterning methods, spring elements 16 or the like having a thickness of first functional layer 10. During this etching process, the use of an etch stop layer 11 is advantageous in order to avoid damaging the MEMS structures of the second functional layer 20 as much as possible.

Following the etching of first functional layer 10, etch stop layer 11 must be removed using a suitable etching method. As the next production step, as shown in FIG. 5, first a third functional layer 30 or a third wafer is prepared, which serves as part of a hermetic capping of a finished component. For this purpose, indentations are etched in a suitable depth into third functional layer 30 using suitable etching methods.

Subsequently, a connecting layer 31 suitable for the chosen bonding technology is applied on third functional layer 30. For this purpose, connecting layer 31 may be a low-melting glass solder or germanium or gold, etc. Optionally, it is possible to produce through holes for later electrical contacting to the contacting layer 15 in the third functional layer 30 already prior to bonding to first functional layer 10, using a suitable silicon etching method. Following the processing step from FIG. 4, this thus results in an electromechanical layer system 100, which is subsequently processed further for producing a micromechanical component.

FIG. 5 shows a cross section of the wafer stack following the bonding of third functional layer 30 to the wafer stack of first functional layer 10 and second functional layer 20. For bonding third functional layer 30 to first functional layer 10, a suitable bonding method may be used such as for example eutectic bonding, seal glass bonding, thermocompression bonding, silicon-silicon direct bonding or anodic bonding. Opening the access holes for the purpose of electrically contacting contacting layer 15 may be performed by a suitable silicon etching method, preferably by trench etching. The desired thickness of third functional layer 30 may be set prior to or after bonding, preferably by grinding third functional layer 30.

Markings 32 on a top side of third functional layer 30 may likewise be introduced prior to or after bonding using one of the established silicon etching method. This may be done for example by trench etching after bonding. Markings 32 may be used to identify sawing paths for the wafers, to position magnets on the finished component, etc.

The next processing steps concern second functional layer 20, which forms the bottom side of the wafer stack made up of functional layers 10, 20 and 30. As indicated in FIG. 6, second functional layer 20 maybe brought to a suitable target thickness, the entire layer stack being first turned around (not shown) for this purpose. Known methods such as for example the grinding and polishing of silicon may be used for this purpose, or alternatively etching methods over the entire surface (preferably onesidedly since the electrical inputs on the surface of first functional layer 10 are already exposed). As already mentioned, in an alternative use of an SOI or double SOI wafer, it is possible to use an etching process with a stop on buried oxide. In this manner, it is possible to implement very exactly specified thicknesses and very even surfaces of second functional layer 20.

After the target thickness has been set, the second functional layer 20 may now be patterned using known silicon etching methods, for example by trench etching. For this purpose, certain areas of second functional layer 20 are exposed completely and may be used in the MEMS component for example as a movable mirror or the like. In this connection, it is also possible to introduce a blackout structure into subregions of the surface. Optionally, it is also possible to develop spring structures or spring elements (not shown) in second functional layer 20.

If desired, as an alternative to a pure silicon surface, it is also possible to apply a highly reflective metalization layer (not shown) for the purpose of an optical mirror coating. This may be done prior to or after patterning the surface and it may also be done with or without patterning the metalization layer. Following the patterning, the surface is preferably coated with a silver stack, a patterning of the stack being omitted. As FIG. 6 shows, this produces a relatively large optically active movable surface of the bottom side of second functional layer 20, which is able to deflect a laser beam of a specific diameter.

In the next manufacturing step, as indicated in FIGS. 7 and 8, a fourth functional layer 40 or a fourth wafer is first provided with through holes. This is preferably done by anisotropic KOH etching, but may also be achieved by trench etching or sandblasting or mechanically by grinding or milling. Fourth functional layer 40 acts as a spacer between the movable MEMS structure, e.g. in the form of the micromirror of the bottom side of second functional layer 20 and a transparent substrate 41 (e.g., glass), which is applied on fourth functional layer 40 and acts as an optical capping of the micromirror.

For glass there is the option of applying it as a wafer over the entire surface, for example by anodic bonding. For this purpose, transparent substrate 41 may be developed in a planar manner (as shown in FIG. 7) or may be provided with a kink (as shown in FIG. 8), it advantageously being possible in the case of a kinked substrate 41 largely to eliminate zero point reflections in an optical image. In the case of a “kinked” transparent substrate 41, it should be ensured that a thickness of fourth functional layer 40 is of a sufficient magnitude. As an alternative to the optical pedestal shown in FIG. 7, it is also possible to use a pedestal made of deep-drawn glass, which is shown schematically in FIG. 8. FIG. 8 shows a schematic representation of a wafer stack made of a silicon wafer having a transparent substrate 41, which is positioned at an angle above the chip. A conventional so-called “pick-and-place-pedestal” (not shown) may be used as well, as described in German Patent Application No. DE 10 2010 062 118 A1.

FIG. 7 shows a wafer stack made of a silicon wafer including a glass wafer. The silicon wafer is provided with access holes, optionally with a corresponding connecting layer 42 for connection to the wafer stack from FIG. 6. The layer stacks of FIGS. 7 and 8 are called “optical pedestals”, these pedestals being provided with sealing glass in order to be subsequently bonded onto the stack from FIG. 6. It is also possible, however, to use other of the above-mentioned bonding methods.

In one variant, it is possible to insert all transparent substrates 41 in one single process step into fourth functional layer 40, which has the advantage that fourth functional layer 40 has to be heated only once and not at every insertion of transparent substrate 41.

In the final work step, the stack from FIG. 6 is bonded to the optical pedestal. FIGS. 9 and 10 show cross-sectional views of entire stacks when using the optical pedestals shown in FIG. 7 and FIG. 8, respectively. Sealing glass bonding may be used as the bonding method, although all other mentioned bonding methods may be used as well, it being possible that the corresponding layers for the bonds still need to be applied.

During the final bonding process with the complete layer structure, it is possible to enclose a defined gas under a defined pressure in cavity 50 of micromechanical layer system 10, 20, 30, 40. This may be neon, a protective gas or nitrogen, it being alternatively also possible to enclose a vacuum. This makes it possible to achieve optimal damping properties for the movable structures of second functional layer 20. The gas should remain enclosed over a usual operational life of the entire structure so as to allow for optimal operating characteristics of the movable micromirror in the long term.

FIG. 11 shows a basic flow chart of one specific embodiment of the method of the present invention.

In a first step S1, a first functional layer 10 is provided and patterned.

In a second step S2, a second functional layer 20 is provided and patterned.

In a third step S3, the two functional layers 10, 20 are vertically arranged one on top of the other, the two functional layers 10, 20 being functionally coupled to each other.

In summary, the present invention provides a micromechanical layer structure that makes it possible to pattern the micromechanical functional layers required for this purpose independently of one another without having to take mutual design requirements into consideration. Ultimately, this allows for a very high vertical integration density of micromechanically active functional layers, which advantageously makes it possible to achieve very small and thus space-saving geometrical chip areas.

Although the present invention has been described with reference to concrete exemplary embodiments, it is by no means limited to these. One skilled in the art will therefore be able to modify or combine with one another the described features without deviating from the essence of the present invention.

1-10. (canceled)

11. A micromechanical layer system, comprising:
at least two mechanically active functional layers, patterned independently of each other, which are arranged vertically one on top of the other and are functionally coupled to each other.

12. The micromechanical layer system as recited in claim 11, wherein at least one of the two functional layers has a spring element.

13. The micromechanical layer system as recited in claim 11, wherein a bottom side of the second functional layer has a reflective coating.

14. The micromechanical layer system as recited in claim 11, wherein the second functional layer is an SOI wafer or a silicon wafer.

15. The micromechanical layer system as recited in claim 11, wherein the layer system is capped on top by a third functional layer and on the bottom by a fourth functional layer.

16. The micromechanical layer system as recited in claim 15, wherein the third functional layer has notches on top.

17. The micromechanical layer system as recited in claim 15, wherein the fourth functional layer is one of planar or kinked.

18. The micromechanical layer system as recited in claim 11, wherein a defined gas atmosphere is enclosed in a cavity between the functional layers.

19. A method for producing a micromechanical layer system, comprising:
providing and patterning a first functional layer;
providing and patterning a second functional layer; and
arranging the two functional layers vertically one on top of the other, the two functional layers being functionally coupled to each other.

20. The method as recited in claim 19, further comprising:
providing a third and a fourth functional layer;
arranging the third functional layer on the layer system made up of the first functional layer and the second functional layer;
arranging the fourth functional layer below the layer system made up of the first functional layer, the second functional layer and the third functional layer; and
enclosing a defined gas atmosphere in a cavity of the layer system.
